(19) United States
(12) Patent Application Publication
(10) Pub. No.: US 2025/0351391 A1
(43) Pub. Date: Nov. 13, 2025

(54) SEMICONDUCTOR DEVICE

(71) Applicant: SAMSUNG ELECTRONICS CO., LTD., Suwon-si (KR)

(72) Inventors: Taekyun KIM, Suwon-si (KR); Jae Won SHIM, Seoul-si (KR); Min Jong LEE, Seoul-si (KR)

(73) Assignees: SAMSUNG ELECTRONICS CO., LTD., Suwon-si (KR); Korea University Research and Business Foundation, Seoul (KR)

(21) Appl. No.: 19/002,282

(22) Filed: Dec. 26, 2024

(30) Foreign Application Priority Data
May 8, 2024 (KR) 10-2024-0060762

(51) Int. Cl. H10D 1/68; H10B 12/00

(52) U.S. Cl. CPC H10D 1/696; H10B 12/30

(57) ABSTRACT

A semiconductor device includes a capacitor including a lower electrode, an upper electrode, and a dielectric layer between the lower electrode and the upper electrode, wherein at least one of the lower electrode and the upper electrode includes a nanolaminate electrode, wherein the nanolaminate electrode includes a plurality of first material layers and a plurality of second material layers alternately arranged, wherein the plurality of first material layers include indium oxide (In₂O₃), wherein the plurality of second material layers include vanadium oxide (V₂O₅), wherein each of the plurality of first material layers includes multiple layers, and wherein each of the plurality of second material layers includes a monolayer.

### CROSS-REFERENCE TO RELATED APPLICATION

This application is based on and claims priority to Korean Patent Application No. 10-2024-0060762, filed on May 8, 2024, in the Korean Intellectual Property Office, the disclosure of which is incorporated by reference herein in its entirety.

### BACKGROUND

### 1. Field

The disclosure relates to a semiconductor device, and more particularly, to a semiconductor device including a capacitor.

### 2. Description of Related Art

As semiconductor devices have been downscaled, the sizes of capacitors used in dynamic random-access memory (DRAM) devices, and similar device, have also decreased. As the size of capacitors decreases, leakage current may increase. Accordingly, there is a need a high-k dielectric material that may be used as a dielectric layer.

### SUMMARY

Provided is a semiconductor device including a capacitor which has reduced leakage current and a relatively high capacitance even in a high frequency region by employing a novel electrode material having a high work function.

According to an aspect of the disclosure, a semiconductor device including a capacitor including: a lower electrode; an upper electrode; and a dielectric layer between the lower electrode and the upper electrode, wherein at least one of the lower electrode and the upper electrode includes a nanolaminate electrode including a plurality of first material layers and a plurality of second material layers alternately arranged, wherein the plurality of first material layers include indium oxide (In₂O₃), wherein the plurality of second material layers include vanadium oxide (V₂O₅), wherein each of the plurality of first material layers includes multiple layers, and wherein each of the plurality of second material layers includes a monolayer.

According to an aspect of the disclosure, a semiconductor device including: a capacitor including: a lower electrode; an upper electrode; and a dielectric layer between the lower electrode and the upper electrode, wherein at least one of the lower electrode and the upper electrode includes a nanolaminate electrode including a plurality of first material layers and a plurality of second material layers alternately arranged, wherein the plurality of first material layers include indium oxide (In₂O₃), wherein the plurality of second material layers include vanadium oxide (V₂O₅), and wherein the nanolaminate electrode has a work function in a range of 5.2 eV to 5.5 eV.

According to an aspect of the disclosure, a semiconductor device includes: a substrate; a contact structure on the substrate; a lower electrode on the contact structure, the lower electrode having a cylindrical shape and including a first nanolaminate electrode; a dielectric layer on the lower electrode; and an upper electrode on the dielectric layer, wherein the first nanolaminate electrode includes a plurality of first material layers and a plurality of second material layers alternately arranged, wherein the plurality of first material layers include indium oxide (In₂O₃), wherein the plurality of second material layers include vanadium oxide (V₂O₅), wherein each of the plurality of first material layers includes multiple layers, and wherein each of the plurality of second material layers includes a monolayer.

### BRIEF DESCRIPTION OF DRAWINGS

The above and other aspects and features of certain embodiments of the present disclosure will be more apparent from the following description taken in conjunction with the accompanying drawings, in which:

FIG. 1 is a cross-sectional view illustrating a semiconductor device, according to one or more embodiments;

FIG. 2A is a cross-sectional view illustrating a lower electrode of FIG. 1;

FIG. 2B is a cross-sectional view illustrating an upper electrode of FIG. 1;

FIG. 3 is a cross-sectional view illustrating a semiconductor device, according to one or more embodiments;

FIG. 4 is a cross-sectional view illustrating a semiconductor device, according to one or more embodiments;

FIG. 5 is a cross-sectional view illustrating a semiconductor device, according to one or more embodiments;

FIG. 6 is a timing diagram illustrating a method of manufacturing a nanolaminate electrode, according to one or more embodiments;

FIG. 7A is a flowchart schematically illustrating a first material layer deposition cycle;

FIG. 7B is a flowchart schematically illustrating a second material layer deposition cycle;

FIG. 8 is an X-ray diffraction (XRD) analysis graph of a nanolaminate electrode, according to one or more embodiments;

FIG. 9 is a graph showing a resistivity, a carrier mobility, and a carrier concentration of a nanolaminate electrode, according to one or more embodiments;

FIG. 10 is a graph showing binding energy of a nanolaminate electrode, according to one or more embodiments, measured according to ultraviolet photoelectron spectroscopy (UPS);

FIG. 11 is a scanning electron microscopy image of a capacitor, according to a comparative example;

FIG. 12 is a scanning electron microscopy image of a capacitor, according to one or more embodiments;

FIG. 13 is a graph showing a capacitance of a capacitor with respect to a frequency, according to one or more embodiments;

FIG. 14 is a graph showing a capacitance of a capacitor in a high frequency region, according to one or more embodiments;

FIG. 15 is a schematic energy band diagram of a capacitor, according to a comparative example;

FIG. 16 is a schematic energy band diagram of a capacitor, according to one or more embodiments;

FIG. 17 is a graph showing current density of a capacitor with respect to a voltage, according to one or more embodiments;

FIG. 18 is a cross-sectional view illustrating a semiconductor device, according to one or more embodiments;

FIG. 19 is an enlarged view illustrating a region A of FIG. 18;

FIG. 20 is a cross-sectional view illustrating a semiconductor device, according to one or more embodiments;

FIG. 21 is a cross-sectional view illustrating a semiconductor device, according to one or more embodiments; and

FIG. 22 is a cross-sectional view illustrating a semiconductor device, according to one or more embodiments.

### DETAILED DESCRIPTION

Hereinafter, embodiments will be described in detail with reference to the accompanying drawings. The same elements are denoted by the same reference numerals in the drawings, and thus, a repeated description thereof will be omitted.

In the specification, a horizontal direction may include a first horizontal direction (X direction) and a second horizontal direction (Y direction) intersecting each other. A direction intersecting the first horizontal direction (X direction) and the second direction (Y direction) may be referred to as a vertical direction (Z direction). In the specification, a vertical level may be referred to as a height level along the vertical direction (Z direction) of any configuration.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

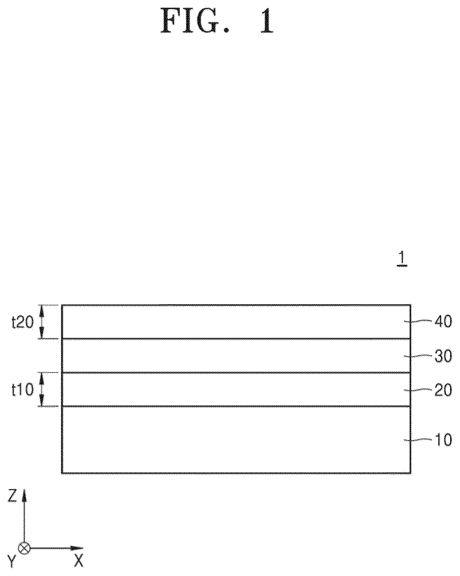

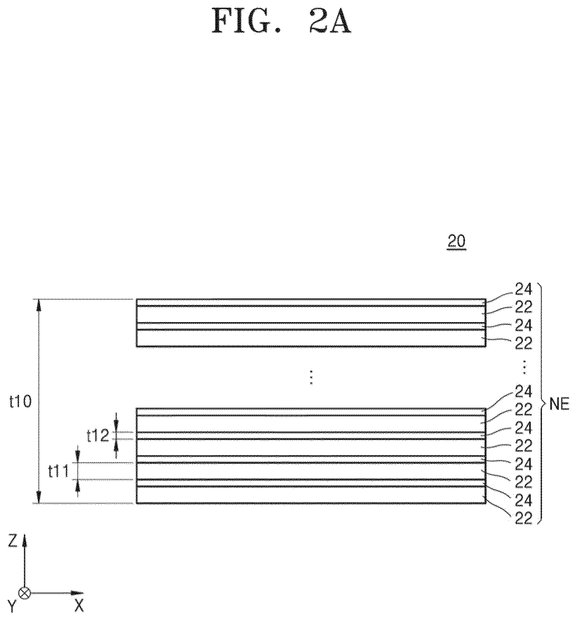

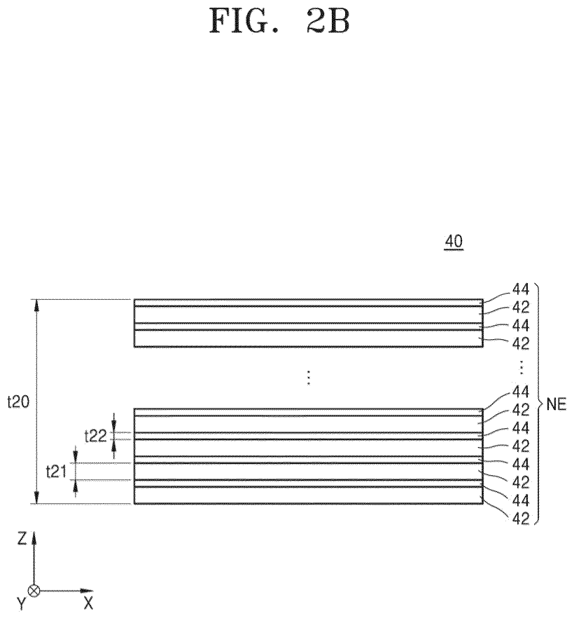

FIG. 1 is a cross-sectional view illustrating a semiconductor device 1, according to one or more embodiments. FIG. 2A is a cross-sectional view illustrating a lower electrode 20 of FIG. 1. FIG. 2B is a cross-sectional view illustrating an upper electrode 40 of FIG. 1.

Referring to FIG. 1, the semiconductor device 1 may include a substrate 10, the lower electrode 20, a dielectric layer 30, and the upper electrode 40. The lower electrode 20, the dielectric layer 30, and the upper electrode 40 may constitute a capacitor. For example, the lower electrode 20, the dielectric layer 30, and the upper electrode 40 may constitute a capacitor having a metal-insulator-metal (MIM) structure.

In one or more embodiments, the lower electrode 20 may include a nanolaminate electrode NE as described with reference to FIG. 2A. The nanolaminate electrode NE may include a plurality of first material layers 22 and a plurality of second material layers 24 alternately arranged.

In one or more embodiments, the plurality of first material layers 22 may include indium oxide. For example, the plurality of first material layers 22 may include indium oxide (In₂O₃). For example, the plurality of first material layers 22 may be formed by using an atomic layer deposition (ALD) process, and each of the plurality of first material layers 22 may have a first thickness t11 of 1.5 nanometers to 11.5 nanometers.

In one or more embodiments, each of the plurality of first material layers 22 may have a multi-layer structure formed by stacking a plurality of monolayers. The term “monolayer” used herein may refer to a single layer in which materials formed by performing one unit cycle for stacking one atomic layer in an ALD process are continuously connected, island-shaped particles, or island-shaped aggregates.

For example, each of the plurality of first material layers 22 may be formed by repeating a first material layer deposition cycle of an ALD process “m” times, where m may be a natural number equal to or greater than 2, for example, 25, 50, 75, 100, 125, or 150.

In one or more embodiments, the plurality of second material layers 24 may include vanadium oxide. For example, the plurality of second material layers 24 may include vanadium oxide (V₂O₅). For example, each of the plurality of second material layers 24 may be formed by using an ALD process. A thickness of each of the plurality of second material layers 24 in the vertical direction (Z direction) may be less than a thickness of each of the plurality of first material layers 22 in the vertical direction (Z direction). For example, each of the plurality of second material layers 24 may have a second thickness t12 of 0.005 nanometers to 0.015 nanometers.

In one or more embodiments, each of the plurality of second material layers 24 may have a monolayer structure. In one or more embodiments, each of the plurality of second material layers 24 may include a single layer continuously connected as shown in FIG. 2A. In one or more embodiments, each of the plurality of second material layers 24 may include island-shaped particles or aggregates arranged on a top surface of each of the plurality of first material layers 22. For example, each of the plurality of second material layers 24 may be formed by repeating a second material layer deposition cycle of an ALD process, “n” times, where n may be a natural number of 1 to 5, for example, 1. The number of repetitions of the second material layer deposition cycle may be less than the number of repetitions of the first material layer deposition cycle. However, the number of repetitions of the first material layer deposition cycle and the number of repetitions of the second material layer deposition cycle are not limited to the numbers described, and may be determined by considering a ratio of indium oxide and vanadium oxide included in the nanolaminate electrode NE.

The lower electrode 20 may be formed by repeating the first material layer deposition cycle for forming each of the plurality of first material layers 22 and the second material layer deposition cycle for forming each of the plurality of second material layers 24 at a certain ratio. The first material layer deposition cycle and the second material layer deposition cycle may be repeatedly performed. For example, the first material layer deposition cycle is performed so that the first material layer 22 has the first thickness t11, and then the second material deposition cycle is performed so that the second material layer has the second thickness t12, and then the first material deposition cycle is performed so that the first material layer 22 has the first thickness t11, and then the second material deposition cycle is performed so that the second material layer has the second thickness t12. Accordingly, the lower electrode 20 may have a thickness t10 of 10 nanometers to 50 nanometers.

In one or more embodiments, the dielectric layer 30 may include metal oxide that is a high-k material. In one or more embodiments, the dielectric layer 30 may include titanium oxide. In other embodiments, the dielectric layer 30 may include at least one of zirconium oxide, hafnium oxide, niobium oxide, tantalum oxide, yttrium oxide, strontium titanium oxide, barium strontium titanium oxide, scandium oxide, and lanthanide oxide.

The upper electrode 40 may include a nanolaminate electrode NE as described with reference to FIG. 2B. The nanolaminate electrode NE may include a plurality of first material layers 42 and a plurality of second material layers 44 alternately arranged. The plurality of first material layers 42 may be configured similarly to the plurality of first material layers 22, and the plurality of second material layers 44 may be configured similarly to the plurality of second material layers 24.

For example, each of the plurality of first material layers 42 may be formed by using an ALD process and may have a first thickness t21 of 1.5 nanometers to 11.5 nanometers. For example, each of the plurality of second material layers 44 may be formed by using an ALD process, and may have a second thickness t22 of 0.005 nanometers to 0.015 nanometers. The upper electrode 40 may have a thickness t20 of 10 nanometers to 50 nanometers.

In one or more embodiments, the nanolaminate NE shown in FIGS. 2A and 2B may have a work function of 5.2 eV to 5.5 eV. Because the nanolaminate electrode NE has a stacked structure of indium oxide and vanadium oxide having a relatively high work function, the nanolaminate electrode NE may have a higher work function than a work function (e.g., 4.5 eV) of an electrode including, for example, titanium nitride (TiN), according to a comparative example.

In one or more embodiments, in an X-ray diffraction analysis result of the nanolaminate electrode NE of FIGS. 2A and 2B, a first peak (211) originated from a plane of indium oxide having a cubic structure, a second peak (222) originated from a plane, and a third peak (400) originated from a plane of the indium oxide are shown. In an X-ray diffraction analysis result of an indium oxide (In₂O₃) electrode according to a comparative example, the nanolaminate electrode NE and the indium oxide electrode may have substantially the same first peak and third peak. The second peak of the nanolaminate electrode NE may be lower than the second peak of the indium oxide electrode. For example, the second peak of the nanolaminate electrode NE may be lower than 30.760 and higher than 30.66°. This may be because an ionic radius of a vanadium atom (about 0.79 Å) is less than an ionic radius of an indium atom (about 0.8 Å), and thus, the vanadium atom may occupy an unoccupied interstitial site of the indium atom, causing lattice contraction of an indium oxide crystal.

In one or more embodiments, the nanolaminate electrode NE shown in FIGS. 2A and 2B may have a carrier concentration equal to or higher than that of the indium oxide electrode, and may have a carrier mobility equal to or higher than that of the indium oxide electrode. Also, the nanolaminate electrode NE of FIGS. 2A and 2B may have a resistivity equal to or lower than that of the indium oxide electrode. For example, the resistivity of the nanolaminate electrode NE may be 0.1 to 1 times the resistivity of the indium oxide electrode.

In one or more embodiments, the lower electrode 20, the dielectric layer 30, and the upper electrode 40 may constitute a MIM-type capacitor, and each of the lower electrode 20 and the upper electrode 40 may include the nanolaminate electrode NE. In one or more embodiments, the lower electrode 20 and the upper electrode 40 may include the nanolaminate electrode NE.

In one or more embodiments, the lower electrode 20 may include the nanolaminate electrode NE, and the upper electrode 40 may not include the nanolaminate electrode NE and may include at least one selected from among a metal such as ruthenium (Ru), titanium (Ti), tantalum (Ta), niobium (Nb), iridium (Ir), molybdenum (Mo), or tungsten (W), a conductive metal nitride such as titanium nitride (TiN), tantalum nitride (TaN), niobium nitride (NbN), molybdenum nitride (MoN), or tungsten nitride (WN), and a conductive metal oxide such as iridium oxide (IrO₂), ruthenium oxide (RuO₂), or strontium ruthenium oxide (SrRuO₃). For example, the upper electrode 40 may include silver oxide (AgO).

In other embodiments, the lower electrode 20 may not include the nanolaminate electrode NE and may include at least one selected from among a metal such as ruthenium (Ru), titanium (Ti), tantalum (Ta), niobium (Nb), iridium (Ir), molybdenum (Mo), or tungsten (W), a conductive metal nitride such as titanium nitride (TiN), tantalum nitride (TaN), niobium nitride (NbN), molybdenum nitride (MoN), or tungsten nitride (WN), and a conductive metal oxide such as iridium oxide (IrO₂), ruthenium oxide (RuO₂), or strontium ruthenium oxide (SrRuO₃). For example, the lower electrode 20 may include silver oxide (AgO). The upper electrode 40 may include the nanolaminate electrode NE.

The nanolaminate electrode NE may have a higher work function than an electrode (e.g., a titanium nitride (TiN) electrode) according to a comparative example, and may have a higher carrier concentration, a higher carrier mobility, and a lower resistivity than an electrode (e.g., an indium oxide (In₂O₃) electrode) according to a comparative example. A work function, a carrier concentration, a carrier mobility, and a resistivity of the nanolaminate electrode NE will be described below in detail.

The capacitor including the lower electrode 20, the dielectric layer 30, and the upper electrode 40 may have a relatively high capacitance value throughout an entire frequency range from a low frequency region to a high frequency region. When the capacitor is defined as having a first capacitance at 1 kHz and has a second capacitance at 1 MHz, in one or more embodiments, the second capacitance may be greater than 40% of the first capacitance. For example, the second capacitance may be greater than 50% of the first capacitance.

Also, due to the nanolaminate electrode NE having a relatively high work function, the capacitor may have a relatively low leakage current by increasing a potential barrier between the nanolaminate electrode NE and a dielectric to effectively block a leakage path of current.

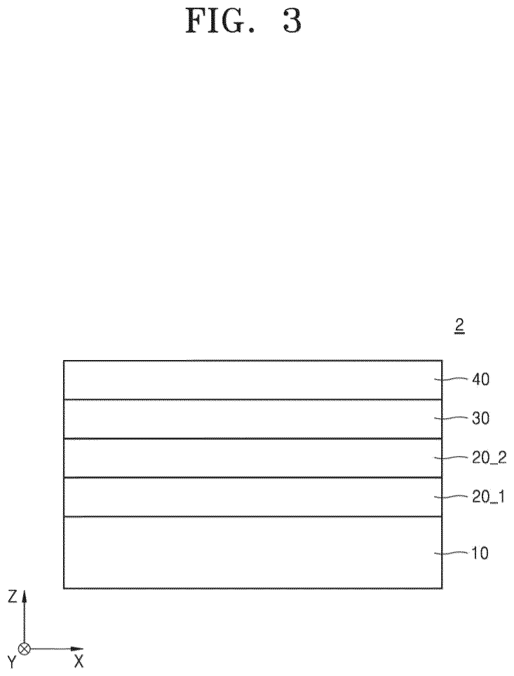

FIG. 3 is a cross-sectional view illustrating a semiconductor device 2, according to one or more embodiments. The semiconductor device 2 is similar to the semiconductor device 1 described with reference to FIGS. 1, 2A, and 2B, except that the semiconductor device 2 includes a first lower electrode 20_1 and a second lower electrode 20_2, and thus, a difference from the semiconductor device 1 will be mainly described.

Referring to FIG. 3, the semiconductor device 2 may include the substrate 10, the first lower electrode 20_1, the second lower electrode 202, the dielectric layer 30, and the upper electrode 40. The first lower electrode 20_1, the second lower electrode 202, the dielectric layer 30, and the upper electrode 40 may constitute a capacitor. For example, the first lower electrode 20_1, the second lower electrode 20_2, the dielectric layer 30, and the upper electrode 40 may constitute an MIM capacitor.

The first lower electrode 20_1 may be located on the substrate 10, and the second lower electrode 202 may be located on the first lower electrode 20_1. The second lower electrode 20_2 may be located between the first lower electrode 20_1 and the dielectric layer 30.

In one or more embodiments, the first lower electrode 20_1 may not include the nanolaminate electrode NE as described with reference to FIG. 2A, and may include at least one selected from among a metal such as ruthenium (Ru), titanium (Ti), tantalum (Ta), niobium (Nb), iridium (Ir), molybdenum (Mo), or tungsten (W), a conductive metal nitride such as titanium nitride (TiN), tantalum nitride (TaN), niobium nitride (NbN), molybdenum nitride (MoN), or tungsten nitride (WN), and a conductive metal oxide such as iridium oxide (IrO₂), ruthenium oxide (RuO₂), or strontium ruthenium oxide (SrRuO₃). For example, the first lower electrode 20_1 may include a single layer electrode (e.g., an electrode including titanium nitride (TiN)). In one or more embodiments, the second lower electrode 20_2 may include the nanolaminate electrode NE as described with reference to FIG. 2A. Each of the first lower electrode 20_1 and the second lower electrode 20_2 may have a thickness of 10 nanometers to 50 nanometers in the vertical direction (Z direction).

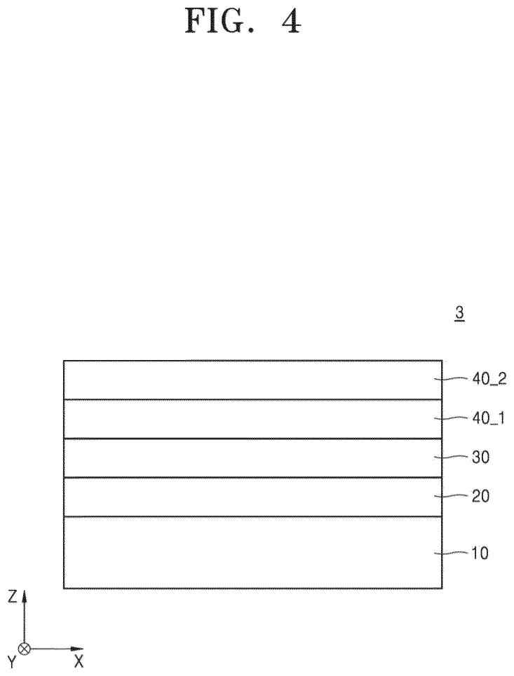

FIG. 4 is a cross-sectional view illustrating a semiconductor device 3, according to one or more embodiments. The semiconductor device 3 is similar to the semiconductor device 1 described with reference to FIGS. 1, 2A, and 2B, except that the semiconductor device 3 includes a first upper electrode 40_1 and a second upper electrode 40_2, and thus, a difference from the semiconductor device 1 will be mainly described.

Referring to FIG. 4, the semiconductor device 3 may include the substrate 10, the lower electrode 20, the dielectric layer 30, the first upper electrode 40_1, and the second upper electrode 40_2. The lower electrode 20, the dielectric layer 30, the first upper electrode 40_1, and the second upper electrode 40_2 may constitute a capacitor. For example, the lower electrode 20, the dielectric layer 30, the first upper electrode 40_1, and the second upper electrode 40_2 may constitute an MIM capacitor.

The first upper electrode 40_1 may be located on the dielectric layer 30, and the second upper electrode 40_2 may be located on the first upper electrode 40_1. The first upper electrode 40_1 may be located between the dielectric layer 30 and the second upper electrode 40_2.

In one or more embodiments, the first upper electrode 40_1 may include the nanolaminate electrode NE as described with reference to FIG. 2B. In one or more embodiments, the second upper electrode 402 may not include the nanolaminate electrode NE as described with reference to FIG. 2B, and may include at least one selected from among a metal such as ruthenium (Ru), titanium (Ti), tantalum (Ta), niobium (Nb), iridium (Ir), molybdenum (Mo), or tungsten (W), a conductive metal nitride such as titanium nitride (TiN), tantalum nitride (TaN), niobium nitride (NbN), molybdenum nitride (MoN), or tungsten nitride (WN), and a conductive metal oxide such as iridium oxide (IrO₂), ruthenium oxide (RuO₂), or strontium ruthenium oxide (SrRuO₃). For example, the second upper electrode 40_2 may include a single layer electrode (e.g., an electrode including titanium nitride (TiN)). Each of the first upper electrode 40_1 and the second upper electrode 40_2 may have a thickness of 10 nanometers to 50 nanometers in the vertical direction (Z direction).

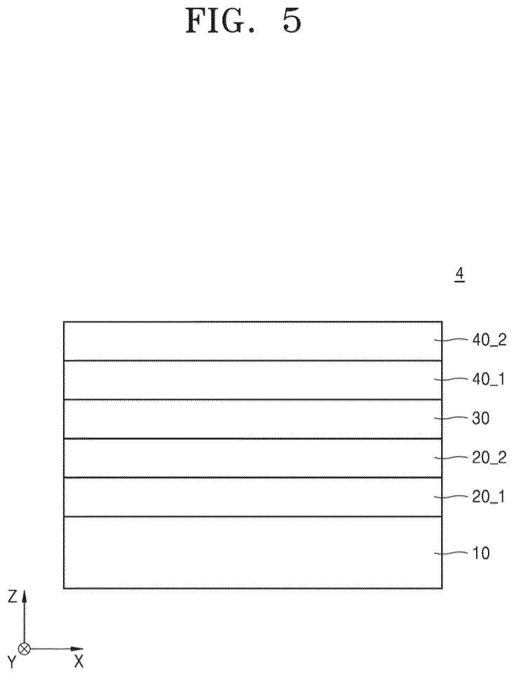

FIG. 5 is a cross-sectional view illustrating a semiconductor device 4, according to one or more embodiments. The semiconductor device 4 is similar to the semiconductor device 1 described with reference to FIGS. 1, 2A, and 2B, except that the semiconductor device 4 includes the first lower electrode 20_1, the second lower electrode 20_2, the first upper electrode 40_1, and the second upper electrode 402, and thus, a difference from the semiconductor device 1 will be mainly described.

Referring to FIG. 5, the semiconductor device 4 may include the substrate 10, the first lower electrode 20_1, the second lower electrode 202, the dielectric layer 30, the first upper electrode 40_1, and the second upper electrode 40_2. The first lower electrode 20_1, the second lower electrode 20_2, the dielectric layer 30, the first upper electrode 40_1, and the second upper electrode 40_2 may constitute a capacitor. For example, the first lower electrode 20_1, the second lower electrode 202, the dielectric layer 30, the first upper electrode 40_1, and the second upper electrode 40_2 may constitute an MIM capacitor.

The first lower electrode 20_1 may be located on the substrate 10, and the second lower electrode 202 may be located on the first lower electrode 20_1. The second lower electrode 20_2 may be located between the first lower electrode 20_1 and the dielectric layer 30.

In one or more embodiments, the first lower electrode 20_1 may not include the nanolaminate electrode NE as described with reference to FIG. 2A. For example, the first lower electrode 20_1 may include a single layer electrode (e.g., an electrode including titanium nitride (TiN)). In one or more embodiments, the second lower electrode 20_2 may include the nanolaminate electrode NE as described with reference to FIG. 2A. Each of the first lower electrode 20_1 and the second lower electrode 20_2 may have a thickness of 10 nanometers to 50 nanometers in the vertical direction (Z direction).

The first upper electrode 40_1 may be located on the dielectric layer 30, and the second upper electrode 40_2 may be located on the first upper electrode 40_1. The first upper electrode 40_1 may be located between the dielectric layer 30 and the second upper electrode 40_2.

In one or more embodiments, the first upper electrode 40_1 may include the nanolaminate electrode NE as described with reference to FIG. 2B. In one or more embodiments, the second upper electrode 402 may not include the nanolaminate electrode NE as described with reference to FIG. 2B. For example, the second upper electrode 40_2 may include a single layer electrode (e.g., an electrode including titanium nitride (TiN)). Each of the first upper electrode 40_1 and the second upper electrode 40_2 may have a thickness of 10 nanometers to 50 nanometers in the vertical direction (Z direction).

The capacitor including the first lower electrode 20_1, the second lower electrode 20_2, the dielectric layer 30, and the upper electrode 40 described with reference to FIG. 3, the capacitor including the lower electrode 20, the dielectric layer 30, the first upper electrode 40_1, and the second upper electrode 40_2 described with reference to FIG. 4, and the capacitor including the first lower electrode 20_1, the second lower electrode 20_2, the dielectric layer 30, the first upper electrode 40_1, and the second upper electrode 40_2 described with reference to FIG. 5 may have a relatively high capacitance value throughout an entire frequency range from a low frequency region to a high frequency region and may have a relatively low leakage current due to the nanolaminate electrode NE having a relatively high work function.

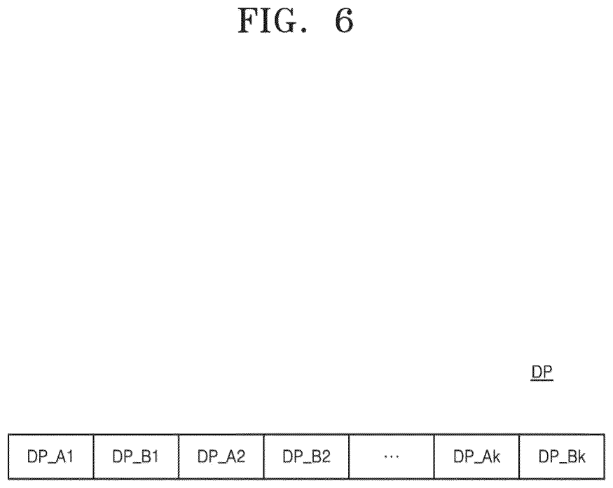

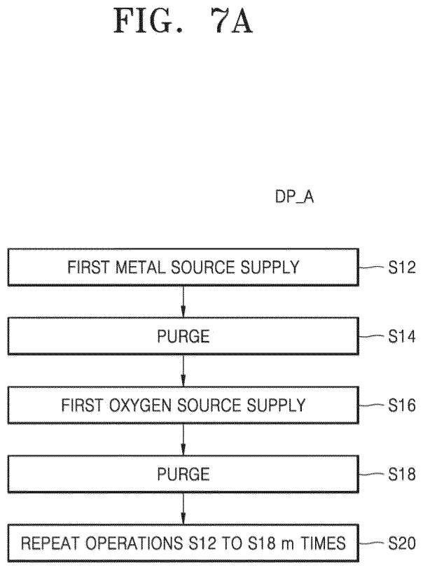

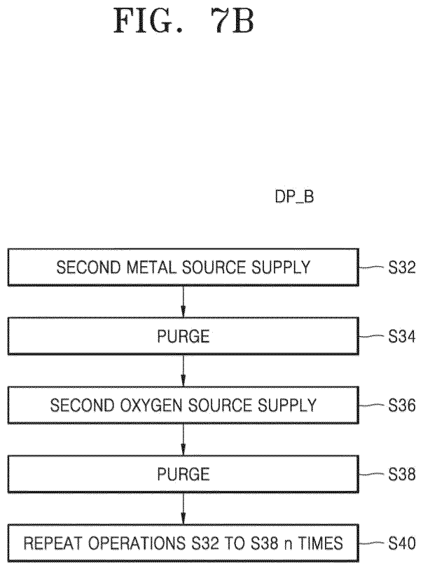

FIG. 6 is a timing diagram illustrating a method DP of manufacturing a nanolaminate electrode, according to one or more embodiments. FIG. 7A is a flowchart schematically illustrating a first material layer deposition cycle DP_A. FIG. 7B is a flowchart schematically illustrating a second material layer deposition cycle DP_B.

Referring to FIGS. 6, 7A, and 7B, the method DP of manufacturing a nanolaminate electrode may be a method based on an atomic layer deposition (ALD) process. For example, the first material layer deposition cycle DP_A and the second material layer deposition cycle DP_B may be sequentially performed on a substrate in a reaction chamber, and a nanolaminate electrode may be formed by repeating the first material layer deposition cycle DP_A and the second material layer deposition cycle DP_B. The first material layer deposition cycle DP_A and the second material layer deposition cycle DP_B may be collectively referred to as a material layer pair deposition cycle.

For example, a nanolaminate electrode may be formed by sequentially performing a first cycle DP_A1 of a first material layer, performing a first cycle DP_B1 of a second material layer, performing a second cycle DP_A2 of the first material layer, performing a second cycle DP_B2 of the second material layer, and then performing a k^{th} cycle DP_Ak of the first material and a k^{th} cycle DP_Bk of the second material layer as shown in FIG. 6. That is, the material layer pair deposition cycle may be repeatedly performed k times. The number k of repetitions of the material layer pair deposition cycle may be determined by considering a total thickness of the nanolaminate electrode and a growth rate of each of the first material layer and the second material layer of the deposition cycle.

As shown in FIG. 7A, the first material layer deposition cycle DP_A may include a unit cycle sequentially including a first metal source supply operation (operation S12) including indium, a first purge operation (operation S14), a first oxygen source supply operation (operation S16), and a second purge operation (operation S18). The first material layer deposition cycle DP_A may include an operation (operation S20) of repeating, m times, the unit cycle sequentially including the first metal source supply operation (operation S12), the first purge operation (operation S14), the first oxygen source supply operation (operation S16), and the second purge operation (operation S18). For example, m may be 25 to 150, or 50 to 125, or 60 to 100. For example, m may be 25, 50, 75, 100, 125, or 150.

In one or more embodiments, in the first metal source supply operation (operation S12), a first metal source may be supplied into the reaction chamber, and the first metal source may be an organometallic precursor including indium. The first metal source may include at least one of trimethyl Indium, In(CH3)3 (TMIn), [1,1,1-trimethyl-N-(trimethylsilyl)silanaminato]indium (InCA-1), [3-(dimethylamino)propyl]dimethyl indium (DADI), and cyclopentadienyl indium (InCp). In one or more embodiments, the first metal source may be, but is not limited to, DADI. For example, the first metal source supply operation (operation S12) may be performed for a period of 0.5 seconds to 3 seconds.

Next, in the first purge operation (operation S14), a remaining first metal source not adsorbed on the substrate may be purged and/or removed. In the first purge operation (operation S14), for example, an argon source including argon (Ar) may be supplied for a period of 10 seconds to 20 seconds.

In the first oxygen source supply operation (operation S16), a first oxygen source may be supplied to the reaction chamber, and the first oxygen source may include at least one of hydrogen peroxide, oxygen, ozone, and oxygen plasma. The first oxygen source may also be referred to as a reactant. In the first oxygen source supply operation (operation S16), a reaction may occur between the first metal source adsorbed on the substrate and the first oxygen source to form a first material layer including indium oxide. For example, the first oxygen source supply operation (operation S16) may be performed for a period of 0.5 seconds to 20 seconds.

Next, in the second purge operation (operation S18), a remaining first oxygen source not adsorbed on the substrate may be purged and/or removed. In the second purge operation (operation S18), for example, after exposure to an argon source including argon (Ar) for 3 seconds to 7 seconds, the argon source may be supplied for a period of 20 seconds to 40 seconds.

For example, an indium oxide layer having a thickness of about 0.07 nanometers to about 0.08 nanometers may be formed for the unit cycle sequentially including the first metal source supply operation (operation S12), the first purge operation (operation S14), the first oxygen source supply operation (operation S16), and the second purge operation (operation S18). In the first material layer deposition cycle DP_A, when the number m of repetitions of the unit cycle is less than 25, it may be difficult for the first material layer (indium oxide) to be formed with a thickness great enough to be crystalized, and when m is greater than 150, the first material layer (indium oxide) may be formed with a too large thickness, and thus, the nanolaminate electrode may have a relatively high resistivity or a relatively low carrier concentration and carrier mobility.

As shown in FIG. 7B, the second material layer deposition cycle DP_B may include a unit cycle sequentially including a second metal source supply operation (operation S32) including vanadium, a first purge operation (operation S34), a second oxygen source supply operation (operation S36), and a second purge operation (operation S38). The second material deposition cycle DP_B may include a operation (operation S40) of repeating, n times, the unit cycle sequentially including the second metal source supply operation (operation S32), the first purge operation (operation S34), the second oxygen source supply operation (operation S36), and the second purge operation (operation S38). Here, n may be 1 to 5, for example, 1.

In one or more embodiments, in the second metal source supply operation (operation S32), a second metal source may be supplied into the reaction chamber, and the second metal source may be an organometallic precursor including vanadium. The second metal source may include at least one of tetrakis(dimethylamino)vanadium, tetrakis[ethylmethylamino]vanadium (TEMAV), vanadium oxytriisopropoxide (VOIP), vanadium triisopropoxide (VTIP), VCl₃, and VCl₄. However, this is only an example, and the second metal source is not limited to the above materials. In one or more embodiments, the second metal source may be, but is not limited to, VTIP. For example, the second metal source supply operation (operation S32) may be performed for a period of 0.5 seconds to 5 seconds.

Next, in the first purge operation (operation S34), a remaining second metal source not adsorbed on the substrate may be purged and/or removed. In the first purge operation (operation S34), for example, an argon source including argon (Ar) may be supplied for a period of 10 seconds to 20 seconds.

In the second oxygen source supply operation (operation S36), a second oxygen source may be supplied into the reaction chamber, and the second oxygen source may include at least one of hydrogen peroxide, oxygen, ozone, and oxygen plasma. The second oxygen source may also be referred to as a reactant. In the second oxygen source supply operation (operation S36), a reaction may occur between the second metal source adsorbed on the first material layer and the second oxygen source to form a second material layer including vanadium oxide. For example, a monolayer of vanadium oxide may be formed on the first material layer. For example, the second oxygen source supply operation (operation S36) may be performed for a period of 0.5 seconds to 20 seconds.

Next, in the second purge operation (operation S38), a remaining second oxygen source not adsorbed on the substrate may be purged and/or removed. In the second purge operation (operation S38), for example, after exposure to an argon source including argon (Ar) for 3 seconds to 7 seconds, the argon source may be supplied for a period of 20 seconds to 40 seconds.

For example, a vanadium oxide layer having a thickness of 0.005 nanometers to 0.015 nanometers may be formed for the unit cycle sequentially including the second metal source supply operation (operation S32), the first purge operation (operation S34), the second oxygen source supply operation (operation S36), and the second purge operation (operation S38). Here, “n” (as recited in operation S40) may be 1 to 5, for example, 1.

In one or more embodiments, the vanadium oxide layer may be formed as a single layer continuously connected on a top surface of the indium oxide layer, or may be formed as island-shaped particles or aggregates located on the top surface of the indium oxide layer.

When a ratio (m:n) of the number of repetitions of the first material layer deposition cycle DP_A to the number of repetitions of the second material layer deposition cycle DP_B ranges from 25:1 to 150:1, the nanolaminate electrode may be formed to have a high work function, a high carrier concentration, a high carrier mobility, and a low resistivity.

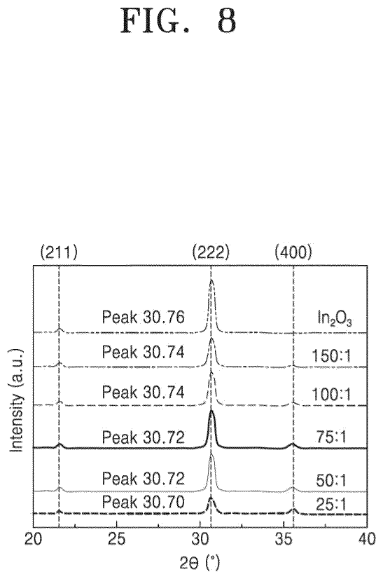

Hereinafter, with reference to Experimental Example 1 regarding the ratio (m:n) of the number of repetitions of the first material layer deposition cycle DP_A to the number of repetitions of the second material layer deposition cycle DP_B, the electrical properties of the nanolaminate electrode according to the ratio of the number of repetitions of the first material layer deposition cycle DP_A to the number of repetitions of the second material layer deposition cycle DP_B will be described in detail in the description of FIGS. 8 to 10.

### Experimental Example 1

A nanolaminate electrode having a thickness of about 20 nm was formed by repeating the first material layer deposition cycle DP_A and the second material layer deposition cycle DP_B at ratios of 150:1, 100:1, 75:1, 50:1, and 25:1 on a substrate in an ALD device. An indium oxide layer having a thickness of about 0.076 nanometers may be formed by performing the first material layer deposition cycle DP_A once, and a vanadium oxide layer having a thickness of about 0.01 nanometers may be formed by performing the second material layer deposition cycle DP_B once. As a comparative example, a single layer electrode of indium oxide (In₂O₃) was formed by performing only the first material layer deposition cycle DP_A.

TABLE 1

| | | V | In | V | In |
|---|---|---|---|---|---|
| Number | In₂O₃:V₂O₅ | Wt % | Wt % | Atomic % | Atomic % |
| Embodiment 1 | 150:1 | 0.77 | 66.54 | 0.72 | 27.64 |
| Embodiment 2 | 100:1 | 0.91 | 65.78 | 0.82 | 26.59 |
| Embodiment 3 | 75:1 | 1.21 | 64.00 | 1.04 | 24.33 |
| Embodiment 4 | 50:1 | 1.51 | 62.32 | 1.25 | 22.13 |
| Embodiment 5 | 25:1 | 0.62 | 67.38 | 1.36 | 21.03 |

TABLE 2

| | | | | The number (k) | |
|---|---|---|---|---|---|
| | | | | of repetitions | |
| | | | | of a material | |
| | | | | layer pair | Thickness |
| Number | In₂O₃:V₂O₅ | DP_A | DP_B | deposition cycle | (nm) |
| Embodiment 1 | 150:1 | 150 times | 1 time | 2 | 22.80 |
| Embodiment 2 | 100:1 | 100 times | 1 time | 3 | 22.83 |
| Embodiment 3 | 75:1 | 75 times | 1 time | 4 | 22.84 |
| Embodiment 4 | 50:1 | 50 times | 1 time | 5 | 19.05 |
| Embodiment 5 | 25:1 | 25 times | 1 time | 10 | 19.10 |

FIG. 8 is an X-ray diffraction analysis graph of a nanolaminate electrode, according to one or more embodiments.

Referring to FIG. 8, X-ray diffraction analysis graphs of Embodiment 1 to Embodiment 5 are illustrated together with an X-ray diffraction analysis graph of Comparative Example. Referring to the X-ray diffraction analysis graphs of Embodiment 1 to Embodiment 5, a first peak (211) originated from a plane of indium oxide having a cubic crystal structure, a second peak (222) originated from a plane, and a third peak (400) originated from a plane are shown. It is found that the first peak and the third peak have substantially the same value or similar values but the second peak has different values in Comparative Example and Embodiments 1 to 5. It is found that the second peak has a smaller value in Embodiments 1 to 5 than in Comparative Example. For example, it is found that the second peak has a value of 30.740 in Embodiment 1, a value of about 30.74° in Embodiment 2, a value of about 30.72° in Embodiment 3, a value of about 30.72° in Embodiment 4, a value of about 30.70° in Embodiment 5, and a value of about 30.76° in Comparative Example. This may be because, in Embodiments 1 to 5, an ionic radius (about 0.79 Å) of a vanadium atom is less than an ionic radius (about 0.8 Å) of an indium atom, and thus, the vanadium atom may occupy an unoccupied interstitial site of the indium atom, causing lattice contraction of an indium oxide crystal. Accordingly, the second peak may shift to a lower angle as a ratio of vanadium oxide increases.

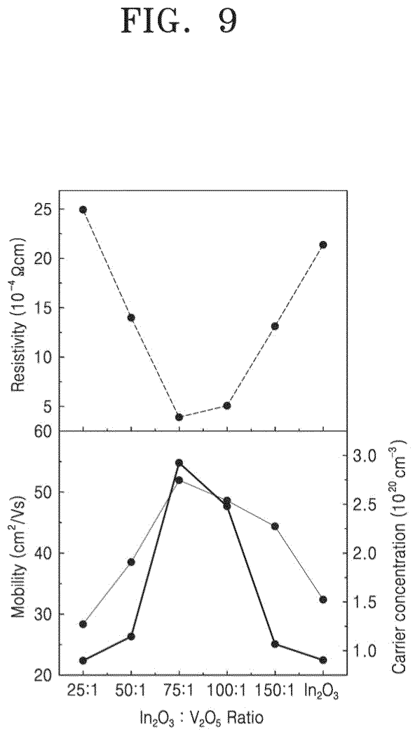

FIG. 9 is a graph showing a resistivity, a carrier mobility, and a carrier concentration of a nanolaminate electrode, according to one or more embodiments.

Referring to FIG. 9, it is found that a resistivity, a carrier mobility, and a carrier concentration of Embodiment 1 to Embodiment 5 are equal to or better than a resistivity and a carrier mobility of Comparative Example. In particular, it is found that Embodiment 3 in which a ratio of In₂O₃:V₂O₅ is 75:1 has a lowest resistivity (e.g., 4.08×10⁻⁴ Ω·cm) and a highest carrier concentration and a highest carrier mobility (52.1 cm²/V·s). It is found that, in Embodiments 1 to 3, as a ratio of In₂O₃:V₂O changes from 150:1 to 75:1 (i.e., as a content of vanadium oxide increases), a resistivity decreases and a carrier concentration and a carrier mobility increase. It is found that, in Embodiments 3 to 5, as a ratio of In₂O₃:V₂O₅ changes from 75:1 to 25:1 (i.e., as a content of vanadium oxide increases), a resistivity increases and a carrier concentration and a carrier mobility decrease. This may be because amorphization of indium oxide is caused by vanadium oxide, or a carrier concentration and a carrier mobility decrease due to a scattering effect due to excessive vanadium oxide.

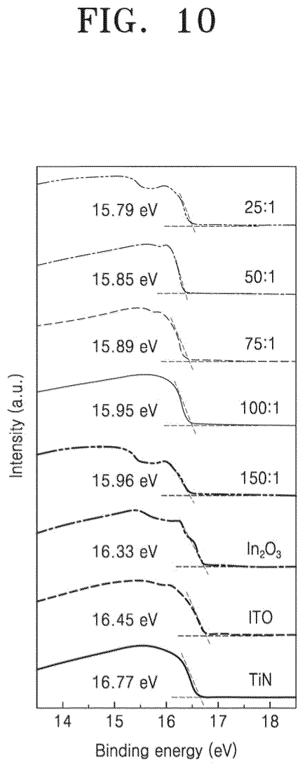

FIG. 10 is a graph showing binding energy of a nanolaminate electrode according to one or more embodiments measured by ultraviolet photoelectron spectroscopy (UPS).

Referring to FIG. 10, binding energy of Embodiments 1 to 5 is illustrated together with binding energy of Comparative Example 1 (indium oxide (In₂O₃)), Comparative Example 2 (indium-tin-oxide (ITO)), and Comparative Example 3 (titanium nitride (TiN)). Work functions of Embodiments 1 to 5, Comparative Example 1, and Comparative Example 2 calculated from binding energy measured by UPS are shown in Table 3.

TABLE 3

| | | Binding energy | Work function |
|---|---|---|---|
| Number | In₂O₃:V₂O₅ | (eV) | (eV) |
| Comparative Example 1 | — | 16.33 | 4.89 |
| Comparative Example 2 | — | 16.45 | 4.77 |
| Comparative Example 3 | — | 16.77 | 4.45 |
| Embodiment 1 | 150:1 | 15.96 | 5.26 |
| Embodiment 2 | 100:1 | 15.95 | 5.27 |
| Embodiment 3 | 75:1 | 15.89 | 5.33 |
| Embodiment 4 | 50:1 | 15.85 | 5.37 |
| Embodiment 5 | 25:1 | 15.79 | 5.43 |

As shown in Table 3, it is found that as a content of vanadium oxide increases, binding energy decreases and a work function increases. Also, it is found that work functions of Embodiments 1 to 5 are 5.2 eV to 5.5 eV higher than work functions of Comparative Examples 1 to 3.

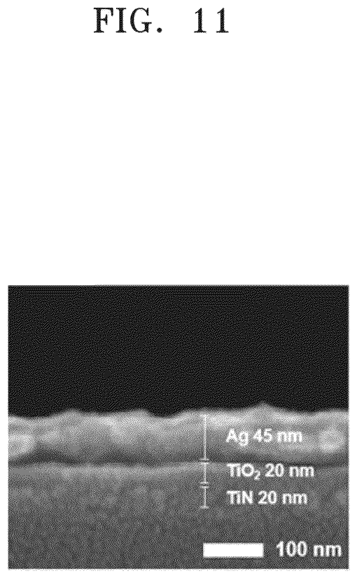

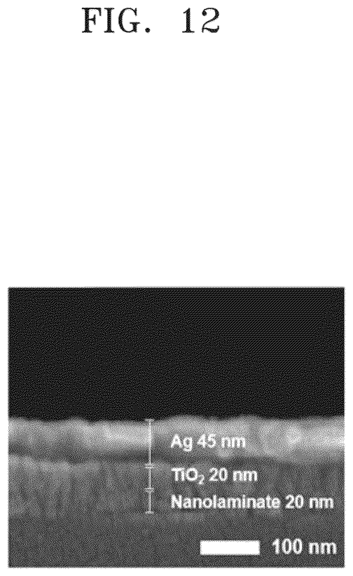

FIG. 11 is a scanning electron microscopy image of a capacitor, according to a comparative example. FIG. 12 is a scanning electron microscopy image of a capacitor, according to an embodiment.

Referring to FIG. 11, it is found that the capacitor according to the comparative example includes titanium nitride (TiN) as a lower electrode, titanium oxide (TiO₂) as a dielectric layer, and silver (Ag) as an upper electrode. Referring to FIG. 12, it is found that the capacitor according to the embodiment includes a nanolaminate electrode (In₂O₃:V₂O₅) as a lower electrode, titanium oxide (TiO₂) as a dielectric layer, and silver (Ag) as an upper electrode. It is found that, like the lower electrode of the comparative example of FIG. 11, the lower electrode (nanolaminate electrode) according to the embodiment of FIG. 12 is a continuous material layer covering an entire substrate and is formed with a uniform thickness. Also, it is found that an interface between the lower electrode (nanolaminate electrode) and the dielectric layer according to the embodiment has good interfacial properties without interfacial defects such as voids or seams.

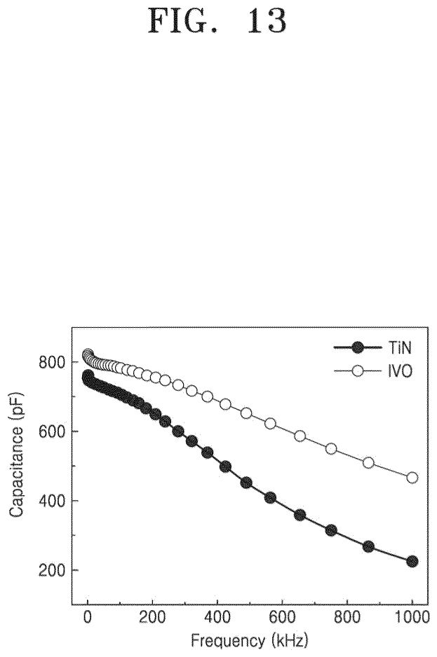

A capacitor according to a comparative example and a capacitor according to an embodiment of FIGS. 13, 14, 15, 16, and 17 described below respectively have configurations of the capacitor according to the comparative example and the capacitor according to the embodiment of FIGS. 11 and 12.

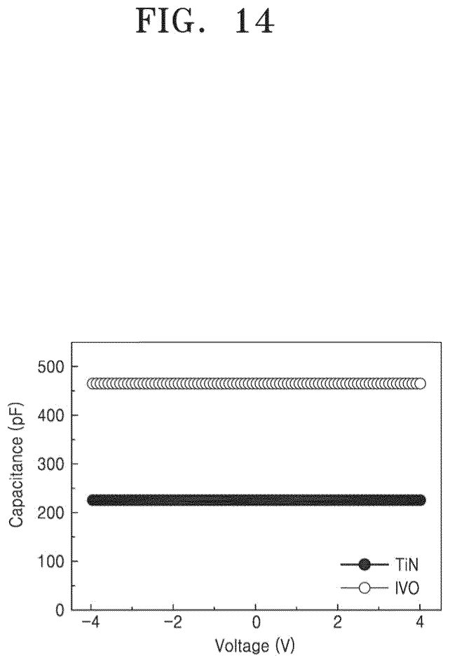

FIG. 13 is a graph showing a capacitance of a capacitor with respect to a frequency, according to an embodiment. FIG. 14 is a graph showing a capacitance of a capacitor in a high frequency region, according to an embodiment.

Referring to FIGS. 13 and 14, a capacitor according to a comparative example had a high capacitance value of 750 pF to 800 pF in a low frequency region of about 1 kHz, but a capacitance value decreased as a frequency increased and the capacitor according to the comparative example had a capacitance value of 200 pF to 250 pF in a high frequency region of about 1 MHz. On the other hand, a capacitor (including a nanolaminate electrode) according to an embodiment had a high capacitance value of 800 pF to 850 pF in a low frequency region of about 1 kHz, and as a frequency value increased, a capacitance value decreased but decreased relatively gradually compared to the capacitor according to the comparative example, and the capacitor according to the embodiment had a capacitance value of 450 pF to 500 pF in a high frequency region of 1 MHz. It is found that, in the high frequency region (e.g., 1 MHz), the capacitance value of the capacitor according to the embodiment is 1.5 to 2.5 times higher than that of the capacitor according to the comparative example.

In general, in a low frequency region, an equivalent series resistance component refers to a value corresponding to dielectric loss due to dielectric relaxation, and as a frequency increases, the influence of series resistance and inductance becomes dominant, and thus, capacitance decreases and equivalent series resistance is affected by loss due to electrodes.

The capacitor according to the embodiment has a dielectric loss factor of 0.1 to 0.2 (e.g., a dielectric loss factor of about 0.115) at 1 MHz, and the capacitor according to the comparative example has a dielectric loss factor of about 1.46 at 1 MHz. Accordingly, it is found that the capacitor according to the embodiment has a significantly lower dielectric loss factor than the capacitor according to the comparator. This may be due to electrical characteristics in which the nanolaminate electrode included in the capacitor according to the embodiment has a relatively low resistivity (i.e., relatively low series resistance) and a relatively high carrier concentration and a relatively high carrier mobility. It may be assumed that the capacitor according to the embodiment has a relatively high capacitance value due to a significantly low dielectric loss factor.

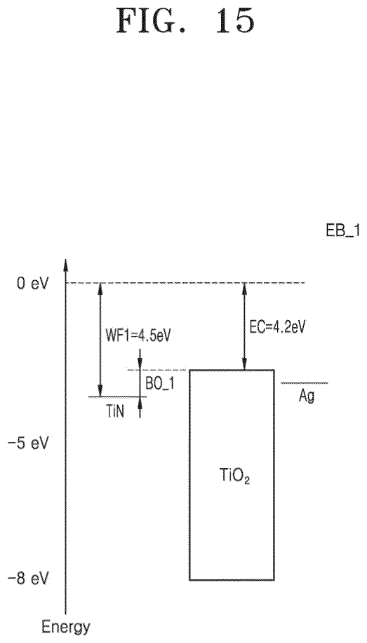

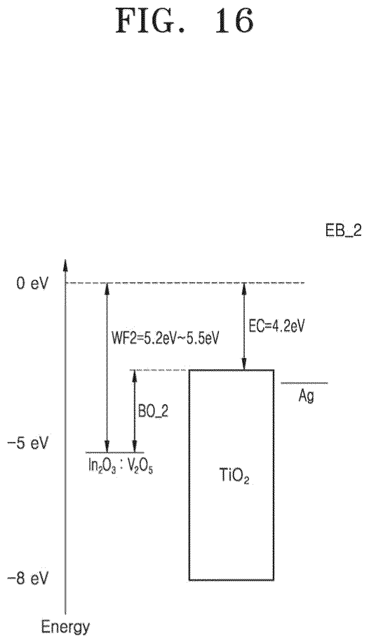

FIG. 15 is a schematic energy band diagram EB_1 of a capacitor according to a comparative example. FIG. 16 is a schematic energy band diagram EB_2 of a capacitor according to an embodiment.

Referring to FIG. 15, in the capacitor according to the comparative example, a work function WF1 of a lower electrode (TiN) is about 4.5 eV, a conduction band EC of a dielectric layer (TiO₂) is about 4.2 eV, and the work function WF1 of the lower electrode (TiN) has a relatively small difference from the conduction band EC of the dielectric layer (TiO₂). Accordingly, a band offset BO_1 at an interface between the lower electrode and the dielectric layer may have a relatively small value. When the band offset at the interface between the lower electrode and the dielectric layer is small, leakage current due to thermionic emission may occur.

Referring to FIG. 16, in the capacitor according to the embodiment, a work function WF2 of a lower electrode (In₂O₃:V₂O₅) is 5.2 eV to 5.5 eV, a conduction band EC of a dielectric layer (TiO₂) is about 4.2 eV, and the work function WF2 of the lower electrode (In₂O₃:V₂O₅) has a relatively large difference from the conduction band EC of the dielectric layer (TiO₂). Accordingly, a band offset BO_2 at an interface between the lower electrode and the dielectric layer may have a relatively large value. When the band offset at the interface between the lower electrode and the dielectric layer is large, leakage current due to thermionic emission may be significantly reduced or prevented.

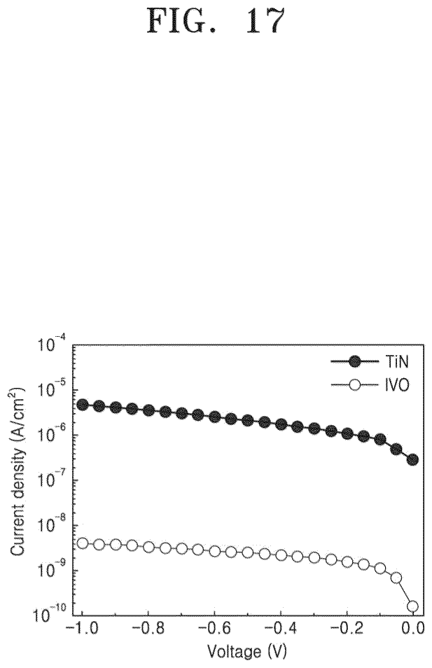

FIG. 17 is a graph showing a current density of a capacitor with respect to a voltage, according to an embodiment.

Referring to FIG. 17, it is found that a capacitor according to a comparative example has a leakage current density of 4.77×10⁻⁶ at 1V whereas a capacitor according to an example has a leakage current density of 4.10×10⁻⁹ at 1V, and thus, the capacitor according to the embodiment has a leakage current density that is 1800 times or more lower than that of the capacitor according to the comparative example.

A narrow band gap of titanium oxide used as a dielectric layer may generate large leakage current due to Schottky emission at an interface between the dielectric layer and an electrode, but because a nanolaminate electrode included in the capacitor according to the embodiment has a relatively high work function as described above, a potential barrier between the electrode and the dielectric layer may be increased to effectively block a leakage path of current, thereby reducing leakage current of the capacitor.

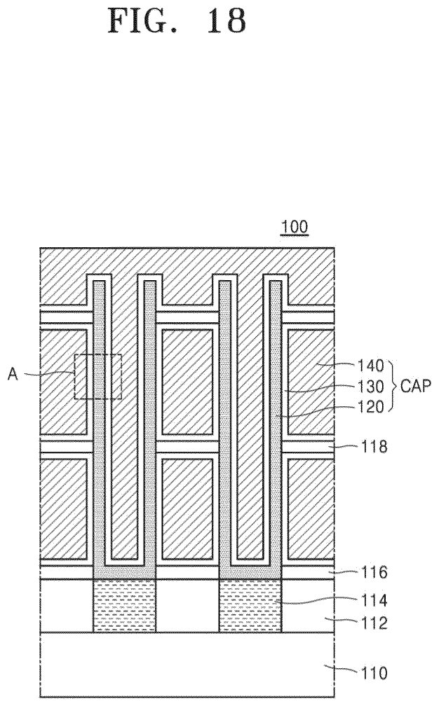

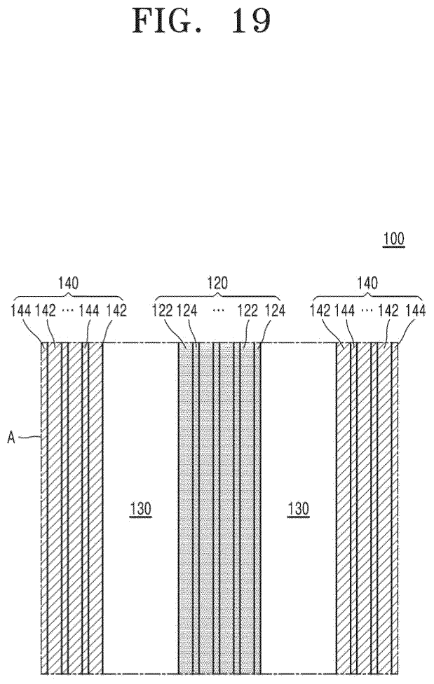

FIG. 18 is a cross-sectional view illustrating a semiconductor device 100, according to one or more embodiments. FIG. 19 is an enlarged view illustrating a region A of FIG. 18.

Referring to FIGS. 18 and 19, the semiconductor device 100 may include a dynamic random-access memory (DRAM) device, and may include a cell transistor formed on a substrate 110 and a capacitor CAP electrically connected to the cell transistor.

A lower insulating layer 112 may be located on the substrate 110, and a contact structure 114 may be located on the substrate 110 to pass through the lower insulating layer 112. The contact structure 114 may include a conductive material. An etch-stop film 116 having an opening through which a top surface of the contact structure 114 is exposed may be located on the lower insulating layer 112.

The capacitor CAP may be located on the etch-stop film 116. The capacitor CAP may include a lower electrode 120, a dielectric layer 130, and an upper electrode 140. The lower electrode 120 may have a cylindrical shape, a side wall of a bottom portion of the lower electrode 120 may be surrounded by the etch-stop film 116, and the bottom portion of the lower electrode 120 may be located on the top surface of the contact structure 114. The lower electrode 120 may have a relatively large height in the vertical direction or may have a large aspect ratio, and a support member 118 may be located on the side wall of the lower electrode 120. The dielectric layer 130 may be conformally located on an inner wall and an outer wall of the lower electrode 120. The upper electrode 140 may be located on the dielectric layer 130 to cover the lower electrode 120.

In one or more embodiments, the lower electrode 120 may include a plurality of first material layers 122 and a plurality of second material layers 124 alternately arranged. The lower electrode 120 may have a structure similar to that of the nanolaminate electrode NE described with reference to FIG. 2A. For example, the plurality of first material layers 122 may include multi-layers including indium oxide, and the plurality of second material layers 124 may include a monolayer including vanadium oxide.

In one or more embodiments, the dielectric layer 130 may include metal oxide that is a high-k material. In one or more embodiments, the dielectric layer 130 may include titanium oxide. In other embodiments, the dielectric layer 130 may include at least one of zirconium oxide, hafnium oxide, niobium oxide, tantalum oxide, yttrium oxide, strontium titanium oxide, barium strontium oxide, scandium oxide, and lanthanide oxide.

In one or more embodiments, the upper electrode 140 may include a plurality of first material layers 142 and a plurality of second material layers 144 alternately arranged. The upper electrode 140 may have a structure similar to that of the nanolaminate electrode NE described with reference to FIG. 2B. For example, the plurality of first material layers 142 may include multi-layers including indium oxide, and the plurality of second material layers 144 may include a monolayer including vanadium oxide.

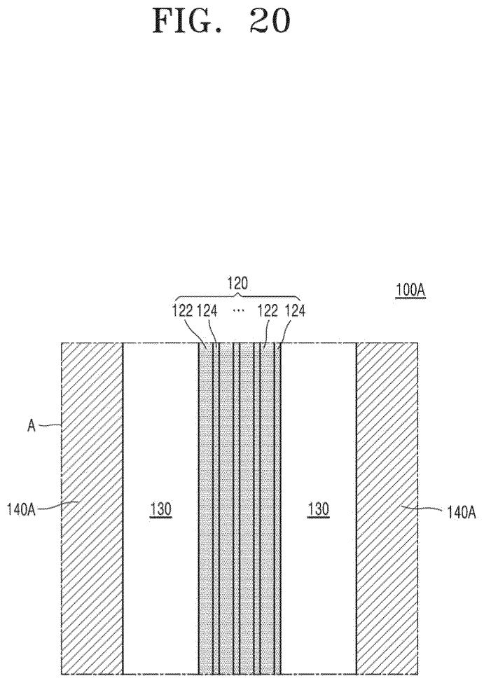

FIG. 20 is a cross-sectional view illustrating a semiconductor device 100A, according to one or more embodiments.

Referring to FIG. 20, the lower electrode 120 may be a nanolaminate electrode including a plurality of first material layers 122 and a plurality of second material layers 124 alternately arranged, and an upper electrode 140A may include at least one selected from among a metal such as ruthenium (Ru), titanium (Ti), tantalum (Ta), niobium (Nb), iridium (Ir), molybdenum (Mo), or tungsten (W), a conductive metal nitride such as titanium nitride (TiN), tantalum nitride (TaN), niobium nitride (NbN), molybdenum nitride (MoN), or tungsten nitride (WN), and a conductive metal oxide such as iridium oxide (IrO₂), ruthenium oxide (RuO₂), or strontium ruthenium oxide (SrRuO₃).

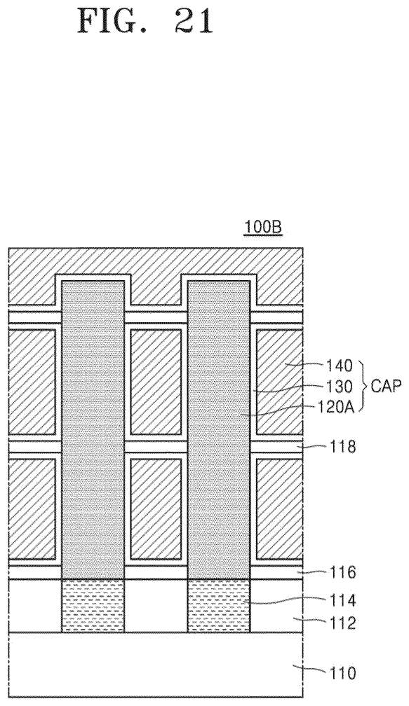

FIG. 21 is a cross-sectional view illustrating a semiconductor device 100B, according to one or more embodiments.

Referring to FIG. 21, a lower electrode 120A may have a pillar shape located on a top surface of the contact structure 114 and extending in the vertical direction. The dielectric layer 130 may be conformally located on a top surface and a side wall of the lower electrode 120A.

In one or more embodiments, the lower electrode 120A may include an integrated material layer extending in the vertical direction, and the lower electrode 120A may include the nanolaminate electrode NE described with reference to FIG. 2A. According to a manufacturing method according to one or more embodiments, the lower electrode 120A may be formed by forming a mold insulating layer having a pillar-shaped opening on the substrate and forming the nanolaminate electrode NE described with reference to FIG. 2A in the opening by using the manufacturing method described with reference to FIGS. 6, 7A and 7B.

In other embodiments, the lower electrode 120A may include a base pillar extending in the vertical direction and an electrode layer conformally located on a side wall and a top surface of the base pillar. The base pillar may include at least one selected from among a metal such as ruthenium (Ru), titanium (Ti), tantalum (Ta), niobium (Nb), iridium (Ir), molybdenum (Mo), or tungsten (W), a conductive metal nitride such as titanium nitride (TiN), tantalum nitride (TaN), niobium nitride (NbN), molybdenum nitride (MoN), or tungsten nitride (WN), and a conductive metal oxide such as iridium oxide (IrO₂), ruthenium oxide (RuO₂), or strontium ruthenium oxide (SrRuO₃), and the electrode layer may include the nanolaminate electrode NE described with reference to FIG. 2A.

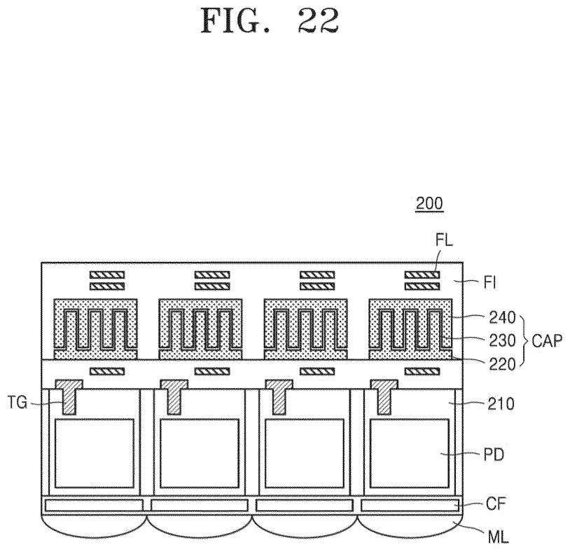

FIG. 22 is a cross-sectional view illustrating a semiconductor device 200, according to one or more embodiments.

Referring to FIG. 22, the semiconductor device 200 may be a global shutter-type image sensor including a plurality of photoelectric conversion regions PD formed on a semiconductor substrate 210 and a capacitor CAP located on a front surface of the semiconductor substrate 210. A transmission gate TG may extend into the semiconductor substrate 210 and may be configured to control photoelectrons stored in the photoelectric conversion region PD. A pixel transistor may be further formed on the front surface of the semiconductor substrate 210, and the pixel transistor may be electrically connected to the capacitor CAP so that charges transferred from the photoelectric conversion region PD of each pixel are stored in the capacitor CAP. The capacitor CAP may include a lower electrode 220, a dielectric layer 230, and an upper electrode 240, and at least one of the lower electrode 220 and the upper electrode 240 may include the nanolaminate electrode NE described with reference to FIGS. 1 to 3. A front wiring layer FL may be located on the front surface of the semiconductor substrate 210, a front insulating layer FI covering the front wiring layer FL and the capacitor CAP may be located, and a color filter CF and a microlens ML may be located on a rear surface of the semiconductor substrate 210.

As described above, one or more embodiments have been illustrated in the drawings and described in the specification. While one or more embodiments have been described using specific terms, this is only used for the purpose of explaining the technical idea of the disclosure and is not used to limit the meaning and scope of the disclosure as recited in the claims. Hence, it will be understood by one of ordinary skill in the art that various modifications and other equivalent embodiments may be made therefrom. Accordingly, the true technical scope of the disclosure should be determined by the technical spirit of the appended claims.

While the disclosure has been particularly shown and described with reference to one or more embodiments thereof, it will be understood that various changes in form and details may be made therein without departing from the spirit and scope of the following claims.

What is claimed is:

1. A semiconductor device comprising:
a capacitor comprising:
a lower electrode;
an upper electrode; and
a dielectric layer between the lower electrode and the upper electrode,
wherein at least one of the lower electrode and the upper electrode comprises a nanolaminate electrode comprising a plurality of first material layers and a plurality of second material layers alternately arranged,
wherein the plurality of first material layers comprise indium oxide (In₂O₃),
wherein the plurality of second material layers comprise vanadium oxide (V₂O₅),
wherein each of the plurality of first material layers comprises multiple layers, and
wherein each of the plurality of second material layers comprises a monolayer.

2. The semiconductor device of claim 1, wherein the lower electrode comprises:
a first lower electrode; and
a second lower electrode on the first lower electrode,
wherein the first lower electrode does not include the nanolaminate electrode,
wherein the first lower electrode comprises at least one selected from among a metal, a conductive metal nitride, or a conductive metal oxide, and
wherein the second lower electrode comprises the nanolaminate electrode.

3. The semiconductor device of claim 1, wherein the upper electrode comprises:
a first upper electrode; and
a second upper electrode on the first upper electrode,
wherein the first upper electrode comprises the nanolaminate electrode, wherein the second upper electrode does not comprise the nanolaminate electrode, and wherein the second upper electrode comprises at least one selected from among a metal, a conductive metal nitride, or a conductive metal oxide.

4. The semiconductor device of claim 1, wherein each of the plurality of first material layers comprises 25 to 150 monolayers.

5. The semiconductor device of claim 1, wherein the plurality of first material layers are included in the nanolaminate electrode at a ratio of 66 wt % to 68 wt %, and
wherein the plurality of second material layers are included in the nanolaminate electrode at a ratio of 0.6 wt % to 0.8 wt %.

6. The semiconductor device of claim 1, wherein the nanolaminate electrode has a work function in a range of 5.2 eV to 5.5 eV.

7. The semiconductor device of claim 1, wherein the capacitor has a first capacitance at 1 kHz and a second capacitance at 1 MHz, and
wherein the second capacitance is greater than 40% of the first capacitance.

8. The semiconductor device of claim 1, wherein the nanolaminate electrode has a thickness in a range of 10 nanometers to 50 nanometers.

9. The semiconductor device of claim 1, wherein the dielectric layer comprises a high-k metal oxide.

10. The semiconductor device of claim 1, wherein, in an X-ray diffraction analysis result, a peak originated from a plane of a crystal structure of the nanolaminate electrode is greater than 30.660 and less than 30.76°.

11. A semiconductor device comprising:
a capacitor comprising:
a lower electrode;
an upper electrode; and
a dielectric layer between the lower electrode and the upper electrode,
wherein at least one of the lower electrode and the upper electrode comprises a nanolaminate electrode comprising a plurality of first material layers and a plurality of second material layers alternately arranged,
wherein the plurality of first material layers comprise indium oxide (In₂O₃),
wherein the plurality of second material layers comprise vanadium oxide (V₂O₅), and
wherein the nanolaminate electrode has a work function in a range of 5.2 eV to 5.5 eV.

12. The semiconductor device of claim 11, wherein each of the plurality of first material layers comprises multiple layers, and
wherein each of the plurality of second material layers comprises a monolayer.

13. The semiconductor device of claim 11, wherein the plurality of first material layers are included in the nanolaminate electrode at a ratio of 66 wt % to 68 wt %, and
wherein the plurality of second material layers are included in the nanolaminate electrode at a ratio of 0.6 wt % to 0.8 wt %.

14. The semiconductor device of claim 11, wherein each of the plurality of first material layers has a first thickness in a range of 1.5 nanometers to 11.5 nanometers, and
wherein each of the plurality of second material layers has a second thickness in a range of 0.005 nanometers to 0.015 nanometers.

15. The semiconductor device of claim 11, wherein the capacitor has a first capacitance at a frequency of 1 kHz and a second capacitance at a frequency of 1 MHz, and
wherein the second capacitance is greater than 50% of the first capacitance.

16. The semiconductor device of claim 11, wherein the nanolaminate electrode has a dielectric loss factor in a range of 0.1 to 0.2 at 1 MHz.

17. A semiconductor device comprising:
a substrate;
a contact structure on the substrate;
a lower electrode on the contact structure, the lower electrode having a cylindrical shape and comprising a first nanolaminate electrode;
a dielectric layer on the lower electrode; and
an upper electrode on the dielectric layer,
wherein the first nanolaminate electrode comprises a plurality of first material layers and a plurality of second material layers alternately arranged,
wherein the plurality of first material layers comprise indium oxide (In₂O₃),
wherein the plurality of second material layers comprise vanadium oxide (V₂O₅),
wherein each of the plurality of first material layers comprises multiple layers, and
wherein each of the plurality of second material layers comprises a monolayer.

18. The semiconductor device of claim 17, wherein each of the plurality of first material layers comprises 25 to 150 monolayers.

19. The semiconductor device of claim 17, wherein the upper electrode comprises a second nanolaminate electrode comprising a plurality of third material layers and a plurality of fourth material layers alternately arranged,
wherein the plurality of third material layers comprise indium oxide (In₂O₃),
wherein the plurality of fourth material layers comprise vanadium oxide (V₂O₅),
wherein each of the plurality of third material layers comprises multiple layers, and
wherein each of the plurality of fourth material layers comprises a monolayer.

20. The semiconductor device of claim 19, wherein each of the plurality of third material layers comprises 25 to 150 monolayers.
